(19) United States
(12) Patent Application Publication
(10) Pub. No.: US 2015/0110989 A1
(43) Pub. Date: Apr. 23, 2015

(54) APPARATUS AND METHOD FOR PROTECTING A COMPONENT

(71) Applicant: Nokia Corporation, Espoo (FI)

(72) Inventors: Zoran RADIVOJEVIC, Cambridge (GB); Chris BOWER, Ely (GB); Joseph BOTTOMLEY, Cambridge (GB)

(21) Appl. No.: 14/510,615

(22) Filed: Oct. 9, 2014

(30) Foreign Application Priority Data
Oct. 23, 2013 (GB) 1318722.4

(51) Int. Cl. H05K 5/06; H01G 11/84; H01M 2/02; H01L 31/18; H01L 31/048; H01G 11/78

(52) U.S. Cl. CPC H05K 5/065; H01L 31/048; H01G 11/78; H01M 2/0202; H01M 2/0237; H01L 31/18; H01G 11/84
USPC 428/69; 29/825

(57) ABSTRACT

According to various, but not necessarily all, examples of the disclosure there may be provided an apparatus and method, the apparatus may comprise: an encapsulated portion configured to receive at least one component wherein the encapsulated portion comprises at least one barrier wall; and a source of gas provided within the encapsulated portion and configured to cause a net flow of gas through the barrier walls from inside the encapsulated portion to outside the encapsulated portion.

### TECHNOLOGICAL FIELD

Examples of the present disclosure relate to an apparatus and method for protecting a component. In particular, they relate to an apparatus and method for encapsulating components such as an electronic component so as to protect the electronic component from contaminants.

### BACKGROUND

Electronic components which are sensitive to contaminants are known. For example displays such as organic light emitting diodes (OLED) displays are sensitive to water and other chemicals found in the air such as oxygen. If an OLED display comes into contact with such contaminants this will degrade the OLED and reduce its useful lifetime. Other volatile material, which may be present in small amounts, could significantly deteriorate the internal structure and functionality of such components.

As another example, photovoltaic cells may be sensitive to contaminants from the atmosphere such as water, gases or dust particles. If a photovoltaic cell display comes into contact with such contaminants this may reduce the efficiency of the photovoltaic cell.

In order to protect such components from contaminants it is known to encapsulate them in a material which acts as a barrier. The barrier material may prevent unwanted contaminants from coming into contact with the sensitive electronic components. Materials such as glass are often used as barrier materials as contaminants such as water, gases and dust cannot penetrate through the glass. However, although glass is an effective barrier it has other limitations. For example, glass is usually rigid or susceptible to cracking which prevents it being used in applications which may require a flexible apparatus.

Therefore it may be advantageous to provide an apparatus and method for encapsulating electronic components which overcomes some of these limitations.

### BRIEF SUMMARY

According to various, but not necessarily all, examples of the disclosure there may be provided an apparatus comprising: an encapsulated portion configured to receive at least one component wherein the encapsulated portion comprises at least one barrier wall; and a source of gas provided within the encapsulated portion and configured to cause a net flow of gas through the bather walls from inside the encapsulated portion to outside the encapsulated portion.

In some examples the at least one component may comprise an electronic component.

In some examples the source of gas may comprise a material provided inside the encapsulated portion which is configured to emit gas. The material configured to emit gas may comprise an adhesive wherein gas is dissolved in the adhesive. The material configured to emit gas may be provided overlaying a component. The material configured to emit gas may be provided on a substrate adjacent to a component.

In some examples the source of gas may be provided by configuring the pressure inside the encapsulated portion to be greater than the pressure outside the encapsulated portion.

In some examples the pressure difference may be created by forming the encapsulated portion at temperatures below the ambient temperature of the apparatus.

In some examples the pressure difference may be created by forming the encapsulated portion at pressures above the ambient pressure of the apparatus.

In some examples the gas provided by the source of gas may comprise an inert gas.

In some examples the gas provided by the source of gas may comprise a hygroscopic gas.

In some examples the at least one component may comprise a display. In some examples the at least one component may comprise a photovoltaic cell. In some examples the at least one component may comprise a sensor. In some examples the at least one component may comprise a super capacitor. In some examples the at least one component may comprise a moisture sensitive device.

In some examples the apparatus may be flexible.

According to various, but not necessarily all, examples of the disclosure there may be provided a method comprising: providing at least one component within an encapsulated portion wherein the encapsulated portion comprises at least one barrier wall; and providing a source of gas provided within the encapsulated portion wherein the source of gas is configured to cause a net flow of gas through the barrier walls from inside the encapsulated portion to outside the encapsulated portion.

In some examples the at least one component may comprise an electronic component.

In some examples the source of gas may comprise a material provided inside the encapsulated portion which is configured to emit gas.

In some examples the material configured to emit gas may comprise an adhesive wherein gas is dissolved in the adhesive. In some examples the material configured to emit gas may be provided overlaying a component. In some examples the material configured to emit gas may be provided on a substrate adjacent to a component.

In some examples the source of gas may be provided by configuring the pressure inside the encapsulated portion to be greater than the pressure outside the encapsulated portion.

In some examples the pressure difference may be created by forming the encapsulated portion at temperatures below the ambient temperature of the apparatus.

In some examples the pressure difference may be created by forming the encapsulated portion at pressures above the ambient pressure of the apparatus.

In some examples the gas provided by the source of gas may comprise an inert gas.

In some examples the gas provided by the source of gas may comprise a hygroscopic gas.

In some examples the at least one component may comprise a display. In some examples the at least one component may comprise a photovoltaic cell. In some examples the at least one component may comprise a sensor. In some examples the at least one component may comprise a super capacitor. In some examples the at least one component may comprise a moisture sensitive device.

In some examples the apparatus is flexible.

The apparatus may comprise one or more electronic components. For example the apparatus may comprise electronic components which may be adversely affected by water and other contaminants, such as displays, sensors, photovoltaic cells or any other suitable electronic components.

### BRIEF DESCRIPTION

For a better understanding of various examples that are useful for understanding the detailed description, reference will now be made by way of example only to the accompanying drawings in which:

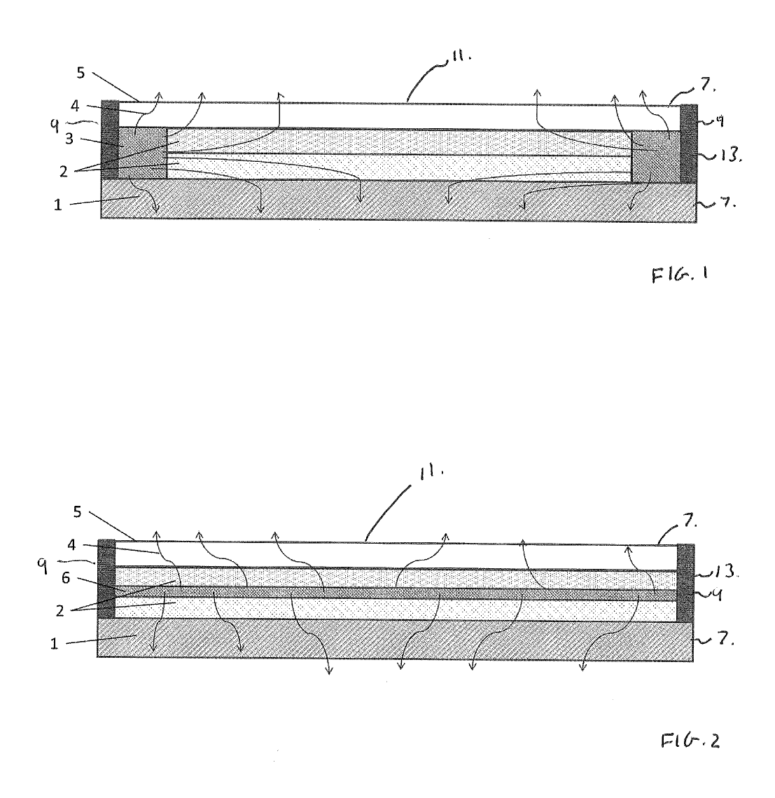

FIG. 1 illustrates an apparatus;

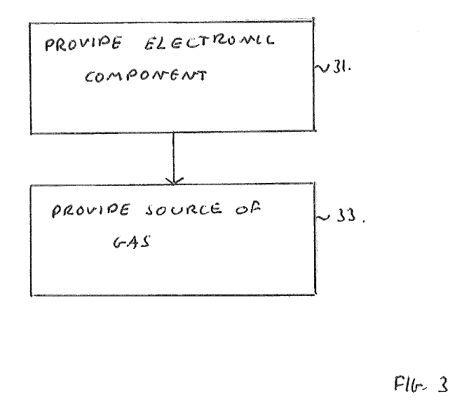

FIG. 2 illustrates an apparatus

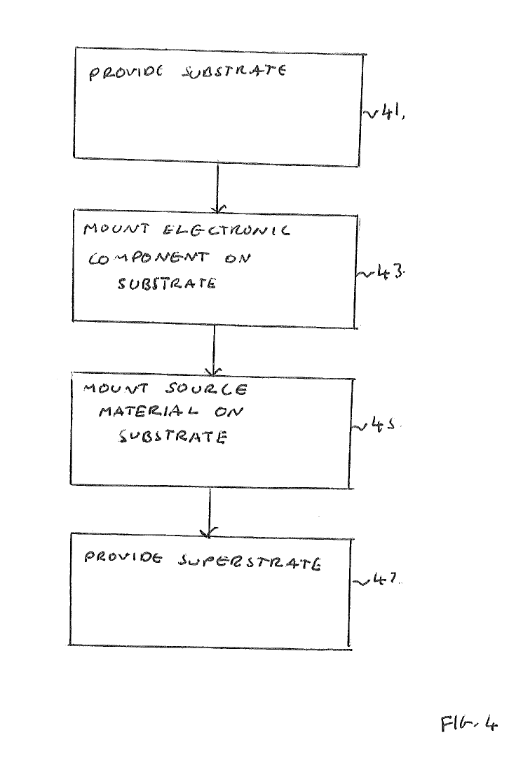

FIG. 3 illustrates a method; and

FIG. 4 illustrates a method.

### DETAILED DESCRIPTION

The Figures illustrate an apparatus 11 and method of providing an apparatus 11 wherein the apparatus 11 comprises: an encapsulated portion 13 configured to receive at least one component 2 wherein the encapsulated portion 13 comprises at least one barrier wall 7; and a source of gas 3, 6 provided within the encapsulated portion 13 and configured to cause a net flow 4 of gas through the barrier walls 7 from inside the encapsulated portion 13 to outside the encapsulated portion 13.

FIG. 1 illustrates a cross section through an example apparatus 11 according to examples of the disclosure. The example apparatus 11 comprises a substrate 1 and a superstrate 5. The substrate 1 and superstrate 5 provide barrier walls 7 for an encapsulated portion 13. The encapsulated portion 13 comprises at least one component 2. The at least one component may comprise an electronic component. In the example of FIG. 1 the electronic component 2 comprises a display such as an OLED display. It is to be appreciated that other types of electronic components could be used in other examples.

The substrate 1 provides a surface which one or more components 2 may be mounted on. In some examples the substrate 1 may be flexible. The flexible substrate 1 may be configured to be bent, stretched, or otherwise deformed in response to a force applied by the user of the apparatus 11.

The substrate 1 may comprise any suitable material such as a flexible metal foil or a polymeric material such as poly(ethyleneterephthalate) (PET), polyethylene 2, 6-napthalate (PEN), polyimide (PI), polycarbonate (PC), polyethylene (PE), polyurethane (PU), polymethylmethacrylate (PMMA), polystyrene (PS), natural rubbers (such as polyisoprenes, polybutadienes, polychloraprenes, polyisobutylenes, nitrile butadienes and styrene butadienes) saturated elastomeric materials (such as polydimethylsiloxane (PDMS), silicone rubbers, fluorosilicone rubbers, fluoroelastomers, perfluoroelastomers, ethylene vinyl acetate (EVA)), thermoplastic elastomers (such as styrene block copolymers, thermoplastic polyolefins, thermoplastic vulcanisates, thermoplastic polyurethane (TPU) thermoplastic copolyesters) and melt processable rubbers or any other suitable material.

The substrate 1 might not be a perfect barrier in that the substrate 1 may allow some contaminants such as water, gas or dust to penetrate through the substrate 1. In such cases it may be beneficial to provide additional protection for the components 2 mounted on the substrate 1.

One or more components 2 may be mounted on the substrate 1. The components may comprise electronic components. In the example of FIG. 1 the electronic component comprises an OLED display 2. The OLED display may comprise a plurality of layers such as an anode, a cathode and layers of organic molecules provided between the anode and cathode. It is to be appreciated that in other examples, other electronic components 2 may be used, such as sensors, photovoltaic cells, batteries or super capacitors or any other sensitive component.

The component 2 may be mounted on the substrate 1 using any suitable means, for example, the component 2 may be adhered to the substrate 1 using any suitable adhesive material.

The component 2 may be flexible. The component 2 may be flexible so that the component 2 and the substrate 1 may be bent or stretched or otherwise deformed in response to a force applied by a user of the apparatus 11.

In the examples of FIG. 1 a source material 3 is also mounted on the substrate 1. In the examples of FIG. 1 the source material is mounted directly on the substrate 1 so that there are no intervening materials between the source material 3 and the substrate 1. In the example of FIG. 1 the source material 3 is provided adjacent to the components 2. In the particular example of FIG. 1 there are no intervening materials between the component 2 and the source material 3. The source material 3 may be in direct contact with the component 2. The source material 3 may be provided so that it has the same thickness as the component 2. This may enable the source material 3 to be included in the apparatus 11 without increasing the thickness of the apparatus 11. The source material 3 may be provided around the edge of the apparatus 11. In the example of FIG. 1 the source material 3 may be non-transparent.

The source material 3 may comprise any material which may be configured to emit gas. In some examples the source material 3 may be configured to emit vapour. The source material 3 may be configured to continually emit gas. In some examples the source material 3 may be configured to emit gas. The gas may be emitted via any suitable process such as outgassing, sublimation or evaporation or any other suitable process.

The source material 3 may comprise a solution into which gases have been dissolved. The dissolved gases may comprise an inert gas such as argon helium or any other suitable gas. The dissolved gases may comprise a dry or hygroscopic gas such as nitrogen, helium, argon or carbon dioxide, or any other suitable gas. The dissolved gases may then be emitted from the source material once the apparatus 1 has been assembled. The emitted gases may provide a flow 4 of gas out of the apparatus 11 as indicated by the arrows in FIG. 1

In some examples the source material 3 may comprise a material which is volatile above a certain temperature. The source material 3 may comprise a getter material. The source material 3 may comprise, for example, a diol such as hexanediol. Hexanediol is a colourless hygroscopic solid which has a melting point of 42° C. in some examples heat generated by the electronic components or other items in the apparatus may be sufficient to melt the hexandiol and allow for the controlled release of gaseous diol. Other diols may be used to adjust the melting point of the source material 3. For example octanediol may be added to increase the melting point whereas pentanediol, which is liquid at room temperature, may be added to lower the melting temperature

A superstrate 5 is provided overlaying the component 2 and the source material 3. In some examples the superstrate 5 may directly overlay the component 2 so that there is no intervening material between the component 2 and the superstrate 5.

The superstrate 5 may be flexible. The superstrate 5 may be flexible so that the superstrate 5 may be bent or stretched or otherwise deformed in response to a force applied by a user of the apparatus 11.

In some examples the superstrate 5 may be transparent. For example, where the component 2 comprises a display the superstrate 5 may be configured to enable a user to view the display through the superstrate 5.

The superstrate 5 may be made of any suitable material. The superstrate 5 might not be a perfect barrier in that the superstrate 5 may allow some contaminants such as water, gas or dust to penetrate through the superstrate 5. In such cases it may be beneficial to provide additional protection for the components 2 mounted on the substrate 1.

The substrate 1 and the superstrate 5 may be coupled to together to form an encapsulated portion 13 which surrounds the components 2 and the source material 3. The substrate 1 and the superstrate 5 provide at least some of the barrier walls 7 of the encapsulated portion 13.

In the particular example of FIG. 1 the apparatus also comprises side walls 9. The side walls 9 may connect the superstrate 5 to the substrate to provide the encapsulated portion 13. The side walls 9 may be made of any suitable material.

The materials used for the barrier walls 7 of the encapsulated portion 13 may provide an imperfect barrier to contaminants. That is, the materials and thicknesses of the materials used may be penetrable by contaminants such as water and/or other liquids, gases such as oxygen and solid particles such as dust. However, in the example of FIG. 1 the source material 3 is provided within the encapsulated portion 13 and is continually providing a flow 4 of gas. This may cause the pressure inside the encapsulated portion 13 to be greater than the pressure outside the encapsulated portion 13. The pressure difference may cause a net flow 4 of gas through the barrier walls 7 from inside the encapsulated portion 13 to outside the encapsulated portion 13.

The pressure difference between the inside of the encapsulated portion 13 and outside the encapsulated portion 13 may also be increased by forming the encapsulated portion 13 at temperatures below the ambient temperature of the apparatus 11. For example if the apparatus 11 is intended to be used at room temperature the apparatus 1 may be assembled at a temperature between 0 to 10° C. It is to be appreciated that other temperature ranges may be used in other applications. It is also to be appreciated that using a lower temperature may create a larger pressure difference. The larger pressure difference may allow for the net pressure difference to be maintained for a longer period of time and so may increase the lifetime of the apparatus 11.

In some examples the pressure difference between the inside of the encapsulated portion 13 and the outside of the encapsulated portion 13 may also be increased by forming the encapsulated portion at pressures higher than the ambient pressure of the apparatus 1. This may also increase the amount of gas which may be dissolved in a source material.

The flow 4 of gas may also act to remove any contaminants from the encapsulated portion. For example a hygroscopic gas may absorb and remove any water from the encapsulated portion 13.

FIG. 2 illustrates a cross section through another example apparatus 11 according to examples of the disclosure. The example apparatus 11 of FIG. 2 comprises a substrate 1 and a superstrate 5. The substrate 1 and superstrate 5 may be as described above in relation to FIG. 1. The apparatus 11 of FIG. 2 also comprises at least one component 2 within an encapsulated portion 13. In the example of FIG. 2 the component 2 also comprises a display such as an OLED display. It is to be appreciated that other types of components could be used in other examples.

As in the example of FIG. 1 one or more components 2 may be mounted on the substrate 1. In the example of FIG. 2 the one or more components comprises a multilayered component such as an OLED display 2. The example apparatus 11 of FIG. 2 differs from the example apparatus 11 of FIG. 1 in that in FIG. 2 the source material 6 is provided overlaying at least a portion of the components 2. In the particular example of FIG. 2 the source material 6 is provided as a layer between two layers of the component 2.

In the example of FIG. 2 the source material 6 may be distributed throughout the electronic component 2. The source material 6 may distributed so that it covers the same surface area as the components 2.

The source material 6 may comprise an adhesive. The adhesive may be used to secure layers of the apparatus 11 together. In the example of FIG. 2 the adhesive may be used to secure layers of the OLED display, or other type of electronic component together. The adhesive may comprise and optically clear adhesive (OCA) or a liquid optically clear adhesive (LOCA). Example materials which may be used comprise acrylic, polyurethane, methylmethacrylate or silicone-based, epoxy based materials. The LOCAs may be cured using any suitable technique such as Ultraviolet curing or thermal curing. In some examples the LOCAs may be “moisture” curable which may require a combination of moisture and ultraviolet radiation. In some examples the LOCAs may be cured chemically by addition of a chemical cross-linker. The chemical curing may be catalyzed by a metal.

The adhesive may be configured to allow the apparatus 11 to be bent or stretched. The adhesive may be configured to allow the apparatus 11 to be bent or stretched in response to a force applied by a user. The adhesive may be configured to allow for slip between the various component layers. In some examples the adhesive may also provide strain relief to protect other components from breaking when the apparatus 11 is bent or otherwise deformed.

The source material 6 may also comprise any material which may be configured to emit gas. In some examples the source material 3 may be configured to emit vapour. The source material 6 may be configured to continually emit gas. The gas may be emitted via any suitable process such as outgassing, sublimination or evaporation or any other suitable process. In some examples the source material 6 may be configured to evolve gas.

The source material 6 may comprise a solution into which gases have been dissolved. The dissolved gases may comprise an inert gas such as argon helium or any other suitable gas. The dissolved gases may comprise a dry or hygroscopic gas such as nitrogen, helium, argon or carbon dioxide, or any other suitable gas. The dissolved gases may then be emitted from the source material once the apparatus 1 has been assembled. The emitted gases may provide a flow 4 of gas out of the apparatus 11 as indicated by the arrows in FIG. 2.

The source material 6 may be provided within the encapsulated portion 13 to cause the pressure inside the encapsulated portion 13 to be greater than the pressure outside the encapsulated portion 13. The pressure difference may cause a net flow 4 of gas through the barrier walls 7 from inside the encapsulated portion 13 to outside the encapsulated portion 13 as described above in relation to FIG. 1.

Also as described above in relation to FIG. 1, the pressure difference between the inside of the encapsulated portion 13 and outside the encapsulated portion 13 may also be increased by forming the encapsulated portion 13 at temperatures below the ambient temperature of the apparatus 11. For example if the apparatus 11 is intended to be used at room temperature the apparatus 1 may be assembled at a temperature between 0 to 10° C. It is to be appreciated that other temperature ranges may be used in other applications. It is also to be appreciated that using a lower temperature may create a larger pressure difference. The larger pressure difference may allow for the net pressure difference to be maintained for a longer period of time and so may increase the lifetime of the apparatus 11.

In some examples the pressure difference between the inside of the encapsulated portion 13 and the outside of the encapsulated portion 13 may also be increased by forming the encapsulated portion at pressures higher than the ambient pressure of the apparatus 1. This may also increase the amount of gas which may be dissolved in a source material.

The flow 4 of gas may also act to remove any contaminants from the encapsulated portion. For example a hygroscopic gas may absorb and remove any water from the encapsulated portion 13.

FIG. 3 illustrates a method of assembling an apparatus 11 according to examples of the disclosure. The apparatus 11 which is assembled may be as described above in relation to FIGS. 1 and 2.

The method comprises, at block 31, providing at least one component 2 within an encapsulated portion where the encapsulated portion comprises at least one barrier wall. The component may comprise an electronic component. The electronic component may be any suitable component such as a display or flexible display. The flexible display could comprise any suitable type of display such as, Organic Light Emitting Diodes (OLEDs), Liquid Crystal Display (LCD), Polymer Dispersed Liquid Crystal (PDLC) or other reflective LCD displays, Electrophoretic (EP), Electroluminescent (EL), Electrowetting (EW) Electrochromic (EC), or other displays which use optical modulation effects such as interference based on frustrated internal reflection or Fabry-Perot cavities.

It is to be appreciated that other electronic components could also be used instead of, or in addition to, the displays described above. For example the electronic components could also comprise components such as photovoltaic cells, batteries, sensors or super capacitors or any other type of component. The component may comprise a moisture sensitive device. In some examples the component may comprise an oxygen sensitive device.

The method also comprises, at block 33, providing a source of gas within the encapsulated portion 13. The source of gas may be configured to cause a net flow 4 of gas through the barrier walls 7 from inside the encapsulated portion to outside the encapsulated portion.

In some examples the source of gas may be provided by configuring the pressure inside the encapsulated portion 13 to be greater than the pressure outside the encapsulated portion 13. In some examples the pressure difference may be achieved by providing a source material 3, 6 inside the encapsulated portion 13 which is configured to emit gas. In some examples the pressure difference may be achieved by forming the encapsulated portion 13 at temperatures below the ambient temperature of the apparatus 11. In some examples the source material 3, 6 may be used and the apparatus 11 may be formed at a low temperature. This may provide for a greater pressure difference which may enable the component 2 to be protected for longer. In some examples the pressure difference may be achieved by forming the encapsulated portion 13 at a pressure above the ambient pressure of the apparatus 11. This may be achieved by forming the encapsulated portion 13 in a pressurised environmental chamber.

FIG. 4 illustrates another method of assembling an apparatus 11 according to examples of the disclosure. The apparatus 11 which is assembled may be as described above in relation to FIGS. 1 and 2.

The method comprises, at block 41, providing a substrate 1. The substrate 1 may be as described above in relation to FIGS. 1 and 2.

At block 43 the method comprises mounting at least one component 2 onto the substrate 1. The component may comprise an electronic component 2. The electronic component 2 may comprise, for example, an OLED display or a photovoltaic cell or any other suitable type of component 2.

The component 2 may be mounted on the substrate 1 using any suitable technique.

At block 45 a source material 3, 6 may also be mounted on to the substrate 1. In some examples the source material 3, 6 may be mounted directly onto the substrate 1. For example the source material 3 may be provided adjacent to the components 2 as illustrated in FIG. 1. In other examples the source material 6 may be provided overlaying at least some of the component 2 as illustrated in FIG. 2 so that the source material 6 is indirectly mounted on the substrate 1.

The source material 3, 6 which is used may depend on the components 2 which are used and whether the source material 3, 6 is provided adjacent to or overlaying the component 2.

The source material 3, 6 may comprise naphthalene, iodine, camphor, menthol, 1.4-dichlorobenzene, fragrance materials, pre-gassed clays, pre-gassed zeolites, pre-gassed graphene or any material such as a nanoporous material which can act as a gas source. In some examples the source material 3, 6 may be transparent, for example where the source material 3, 6 overlays a display. In such examples the source material 3, 6 may comprise a material such as camphor, menthol or pre-gassed graphene.

In some examples the source material 3, 6 may comprise a liquid or a mix of liquid and a solid such as benzophenone and sodium. In some examples the source material 3, 6 may comprise a material which degrades and forms gaseous products as it degrades. In some examples the source material 3, 6 may comprise a solid and a highly viscous fluid which may react to provide gaseous by-products.

At block 47 a superstrate is provided overlaying the component 2 and source material 3, 6. The superstrate 5 and the substrate 1 may be configured to encapsulate the component 2 and the source material 3,6 so that the component 2 and the source material 2 are completely surrounded by barrier walls.

It is to be appreciated that blocks 43 and 45 may be carried out in any order. The source materials 3, 6 and the components 2 which are to be housed within the encapsulated portion may be dried before the superstrate is provided. This may ensure that there are no internal sources of moisture within the apparatus 11.

Blocks 43 to 47 may be carried out at a low temperature and/or high pressure to increase the pressure with the encapsulated portion 13 when the apparatus 11 is in use.

The blocks illustrated in FIGS. 3 and 4 may represent steps in a method. The illustration of a particular order to the blocks does not necessarily imply that there is a required or preferred order for the blocks and the order and arrangement of the block may be varied. Furthermore, it may be possible for some blocks to be omitted.

The apparatus 11 and methods described above enable sensitive components 2 such as electronic components to be encapsulated and protected from contaminants. As the pressure difference provides a net flow of gas out of the encapsulated portion 13 this means that the barrier walls 7 of the encapsulated portion 13 do not need to be impermeable. This may enable flexible materials to be used to encapsulate the components 2 and so provide a flexible apparatus 11.

The examples of the disclosure may be particularly beneficial for use in apparatus 11 which may be bent or stretched. The barrier walls 7 of such apparatus 11 are likely to become more porous when the apparatus 11 is bent or stretched. As the inside of the encapsulated portion 13 has a higher pressure than the outside of the encapsulated portion 13 this causes the net flow 4 of gas out of encapsulated portion and so protects the electronic components even when the apparatus 11 is bent or stretched.

In some apparatus 11 the source material 3, 6 may also be used as an adhesive to secure components 2 or other portions of the apparatus 11 together. This may enable a thin or small apparatus 11 to be provided as there is no requirement to introduce in an additional element.

The disclosure also allows for a simpler method of assembling the apparatus 11 because the apparatus 11 does not require multiple layers to create a barrier wall 7.

In some examples the gas which is emitted from the source material 3, 6 may be chosen to have a pleasant smell. This may be aesthetically pleasing for the user of the apparatus 11. It may also be used to differentiate one apparatus 11 from another.

The term “comprise” is used in this document with an inclusive not an exclusive meaning. That is any reference to X comprising Y indicates that X may comprise only one Y or may comprise more than one Y. If it is intended to use “comprise” with an exclusive meaning then it will be made clear in the context by referring to “comprising only one . . . ” or by using “consisting”.

In this brief description, reference has been made to various examples. The description of features or functions in relation to an example indicates that those features or functions are present in that example. The use of the term “example” or “for example” or “may” in the text denotes, whether explicitly stated or not, that such features or functions are present in at least the described example, whether described as an example or not, and that they can be, but are not necessarily, present in some of or all other examples. Thus “example”, “for example” or “may” refers to a particular instance in a class of examples. A property of the instance can be a property of only that instance or a property of the class or a property of a sub-class of the class that includes some but not all of the instances in the class.

Although embodiments of the present invention have been described in the preceding paragraphs with reference to various examples, it should be appreciated that modifications to the examples given can be made without departing from the scope of the invention as claimed. For example the apparatus 11 may also comprise getter materials which may be used to absorb any unwanted contaminants within the encapsulated portion. The getter material may comprise any suitable material such as inorganic materials that absorb water. The inorganic materials may comprise, for example, phosphorous pentoxide, calcium chloride, calcium sulfate, calcium oxide, calcium hydride, activated alumina, aerogels, benzophenone, bentonite, montmorillonite, cobalt(II) chloride, copper(II) sulfate, lithium chloride, lithium bromide, lithium-aluminium hydride, magnesium, magnesium sulfate, magnesium perchlorate, magnesium oxide, molecular sieves, potassium carbonate, potassium hydroxide, silica gel, sodium, sodium chlorate, sodium chloride, sodium hydroxide, sodium sulfate, sodium silicate, sucrose, sulphuric acid, alkali metal oxides, alkaline earth metal oxides, metal halides, metal perchlorates, metal sulphates. In some examples the getter materials may be used to absorb oxygen. In such examples the getter materials may comprise materials such as zeolites, calcium carbonate, iron(II) carbonate, iron(II) oxide, activated charcoal, ascorbic acid or any other suitable materials.

Also in the above examples the apparatus comprises a component or device. In other examples perishable goods which may be sensitive to contaminants such as water and/or air may be protected. The source material may be provided in addition to the perishable goods within the encapsulated portion.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

We claim:

1. An apparatus comprising:
an encapsulated portion configured to receive at least one component wherein the encapsulated portion comprises at least one barrier wall; and
a source of gas provided within the encapsulated portion and configured to cause a net flow of gas through the barrier walls from inside the encapsulated portion to outside the encapsulated portion.

2. An apparatus as claimed in claim 1 wherein the at least one component comprises an electronic component.

3. An apparatus as claimed in claim 1 wherein the source of gas comprises a material provided inside the encapsulated portion which is configured to emit gas.

4. An apparatus as claimed in claim 3 wherein the material configured to emit gas comprises an adhesive wherein gas is dissolved in the adhesive.

5. An apparatus as claimed in claim 3 wherein the material configured to emit gas is provided overlaying a component.

6. An apparatus as claimed in claim 3 wherein the material configured to emit gas is provided on a substrate adjacent to a component.

7. An apparatus as claimed in claim 1 wherein the source of gas is provided by configuring the pressure inside the encapsulated portion to be greater than the pressure outside the encapsulated portion.

8. An apparatus as claimed in claim 7 wherein the pressure difference is created by forming the encapsulated portion at temperatures below the ambient temperature of the apparatus.

9. An apparatus as claimed in claim 7 wherein the pressure difference is created by forming the encapsulated portion at pressures above the ambient pressure of the apparatus.

10. An apparatus as claimed in claim 1 wherein the gas provided by the source of gas comprises an inert gas.

11. An apparatus as claimed in claim 1 wherein the gas provided by the source of gas comprises a hygroscopic gas.

12. An apparatus as claimed in claim 1 wherein the at least one component comprises a display.

13. An apparatus as claimed in claim 1 wherein the at least one component comprises a photovoltaic cell.

14. An apparatus as claimed in claim 1 wherein the at least one component comprises a sensor.

15. An apparatus as claimed in claim 1 wherein the at least one component comprises a super capacitor.

16. An apparatus as claimed in claim 1 wherein the at least one component comprises a battery.

17. An apparatus as claimed in claim 1 wherein the at least one component comprises a moisture sensitive device.

18. An apparatus as claimed in claim 1 wherein the apparatus is flexible.

19. A method comprising:
providing at least one component within an encapsulated portion wherein the encapsulated portion comprises at least one barrier wall; and
providing a source of gas provided within the encapsulated portion wherein the source of gas is configured to cause a net flow of gas through the barrier walls from inside the encapsulated portion to outside the encapsulated portion.

20. A method as claimed in claim 19 wherein the at least one component comprises an electronic component.

21. A method as claimed in claim 19 wherein the source of gas comprises a material provided inside the encapsulated portion which is configured to emit gas.

22. A method as claimed in claim 21 wherein the material configured to emit gas comprises an adhesive wherein gas is dissolved in the adhesive.

23. A method as claimed in claim 19 wherein the material configured to emit gas is provided overlaying a component.

24. A method as claimed in claim 19 wherein the material configured to emit gas is provided on a substrate adjacent to a component.

25. A method as claimed in claim 19 wherein the source of gas is provided by configuring the pressure inside the encapsulated portion to be greater than the pressure outside the encapsulated portion.

26. A method as claimed in claim 25 wherein the pressure difference is created by forming the encapsulated portion at temperatures below the ambient temperature of the apparatus.

27. A method as claimed in claim 25 wherein the pressure difference is created by forming the encapsulated portion at pressures above the ambient pressure of the apparatus.

28. A method as claimed in claim 19 wherein the gas provided by the source of gas comprises an inert gas.

29. A method as claimed in claim 19 wherein the gas provided by the source of gas comprises a hygroscopic gas.

30. A method as claimed in claim 19 wherein the at least one component comprises a display.

31. A method as claimed in claim 19 wherein the at least one component comprises a photovoltaic cell.

32. A method as claimed in claim 19 wherein the at least one component comprises a sensor.

33. A method as claimed in claim 19 wherein the at least one component comprises a super capacitor.

34. A method as claimed in claim 19 wherein the at least one component comprises a battery

35. A method as claimed in claim 19 wherein the at least one component comprises a moisture sensitive device.

36. A method as claimed in claim 19 wherein the apparatus is flexible.
